(19) United States
(12) Patent Application Publication
(10) Pub. No.: US 2002/0101256 A1
(43) Pub. Date: Aug. 1, 2002

(54) Detecting failures in printed circuit boards

(76) Inventors: Patrick R. Brown, Greenacres, WA (US); Scott A. Pennestri, Cour d' Alene, ID (US); Wyatt F. Luce, Post Falls, ID (US); Thomas R. Faulkner, Veradale, WA (US)

Correspondence Address: AGILENT TECHNOLOGIES, Legal Department, 51U-PD, Intellectual Property Administration, P.O. Box 58043, Santa Clara, CA, 95052-8043, US

(21) Appl. No.: 09/770,944

(22) Filed: Jan. 26, 2001

(51) Int. Cl. G01R 31/02

(52) U.S. Cl. 324/761

(57) ABSTRACT

Detection of delaminated features on a printed circuit board. Delamination is detected by designing a sacrificial trace which is anchored by a via at one end and connects to a feature such as a pad on the other. The sacrificial trace is fragile. Delamination of the feature causes the sacrificial trace to break, interrupting an electrical circuit which is sensed to detect the failure.

### BACKGROUND OF THE INVENTION

1. Field of the Invention

The present invention relates to the field of printed circuit boards, and to the detection of failures in printed circuit boards, particularly those involving delamination of conductive features.

2. Art Background

Printed circuit boards have become ubiquitous in electronic devices. Consisting of an insulating substrate of a material such as fiberglass, conductive features including pads and traces for interconnecting electronic components are held in place on one or more surfaces of the substrate by an adhesive. A single layer board has conductive features, usually of copper, on one side of the substrate. A double-sided board has conductive features on both sides of the substrate. It is also possible to make multi-layer printed circuit boards, where layers of conductive traces are sandwiched between layers of substrate material. Printed circuit boards having four or more conductive layers are common in the industry. Conductive features known as pads are used for test points and component connection. Connections between pads are made by lines of conductive material known as traces.

Conductive features interconnect between layers using vias. A via is a hole through one or more layers of the substrate, with conductive traces on both sides, and conductive material in the hole providing electrical connection between the traces. The through-hole via may be solid, or may be hollow. Vias may be formed using rivets, or through metal deposition techniques such as plating, well known to the printed circuit manufacturing arts.

Early printed circuit board construction used components having wire leads. Resistors, capacitors, integrated circuits, and other components mounted to the printed circuit board by having holes through the substrate through which component leads passed. Conductive pads surrounded these lead holes, and solder was applied to connect the component leads to the printed circuit board pads. Through-hole mounting also mechanically secured devices in place.

Component and interconnect density in modern electronics continues to increase. Through-hole components are seldom used, replaced by surface-mounting parts. For example, replacing the traditional cylindrical resistor with its radial leads is a surface-mount resistor in the form of a small rectangular chip with conductive surfaces on the ends. The surface-mount component is soldered to pads on the surface of the printed circuit board. Surface mount components also allow a high density of components to be populated on both sides of a printed circuit board.

Integrated circuits are also produced in surface-mount packages. Some packages have leads in the form of the letter “J” which solder to conductive pads. Integrated circuit packages such as SOJ packages only provide electrical contacts along the periphery of the package. An integrated circuit package known as the ball-grid-array, or BGA, provides a rectilinear grid pattern of contacts on the bottom of an integrated circuit device. BGA packages can provide many hundreds or thousands of contacts in a 50 mm by 50 mm space. Multi-chip modules, known as MCM packages, allow multiple integrated circuits to be mounted to a printed circuit board as one device.

Surface mount components, especially high density components such as BGA packaged integrated circuits introduce new failure modes and reliability problems into printed circuit board based electronic devices. Where through-hole mounted components had the additional effect of anchoring traces and pads to the substrate, on a surface-mount board, pads and traces are held in place only by an adhesive bond to the substrate. Vias offer additional structural security, as they involve in effect a metal anchor between layers.

Surface mount components, especially large components such as inductors, and integrated circuit in BGA and MCM packages, are much more rigid than the printed circuit board substrate to which they mount, and additionally usually have differing thermal expansion characteristics. Stresses applied to the completed circuit board causing the substrate to flex may cause pads to delaminate from the substrate as the adhesive holding the pad to the substrate fails. This delamination may be caused by thermal expansion and contraction, or through mechanical events such as sharp shocks encountered when the device is dropped, or other events which may cause the printed circuit board to be flexed. This delamination may result in electrical paths being interrupted. A more insidious failure occurs when a pad and its trace lift off the board, but still provide electrical conductivity, at least until another event occurs, causing the trace to fail.

With many surface mount components, such as common resistors and capacitors, optical inspection may reveal delaminated or broken traces. Components such as BGA and MCM packages, filters, and other components, have packages which may occlude printed circuit board connections. The resulting connections are underneath the component, so any damage to traces is hidden from view, mechanically obscured by the body of the component. Thus, direct or indirect optical visual inspection is not possible. While X-ray techniques may detect some catastrophic failures, X-ray screening cannot provide adequate detection of latent defects.

What is needed is a way to detect delamination of pads on a printed circuit board.

### SUMMARY OF THE INVENTION

Delamination of printed circuit board features are detected by including a sacrificial trace. The sacrificial trace is deliberately made fragile, by being very thin, very narrow, and very short, or by containing stress concentrating points. One end of the sacrificial trace connects to a bonding pad. The other end of the sacrificial trace connects to a via in the printed circuit board which acts as an anchor. Mechanical displacement in the area of interest fractures the deliberately fragile sacrificial trace. Delamination is detected by sensing interrupted continuity between the via and the bonding pad, caused by the failure of the sacrificial trace.

### BRIEF DESCRIPTION OF THE DRAWINGS

The present invention is described with respect to particular exemplary embodiments thereof and reference is made to the drawings in which:

FIG. 1 shows a cross-section of a printed circuit board,

FIG. 2 shows a top view of a printed circuit board

### DETAILED DESCRIPTION

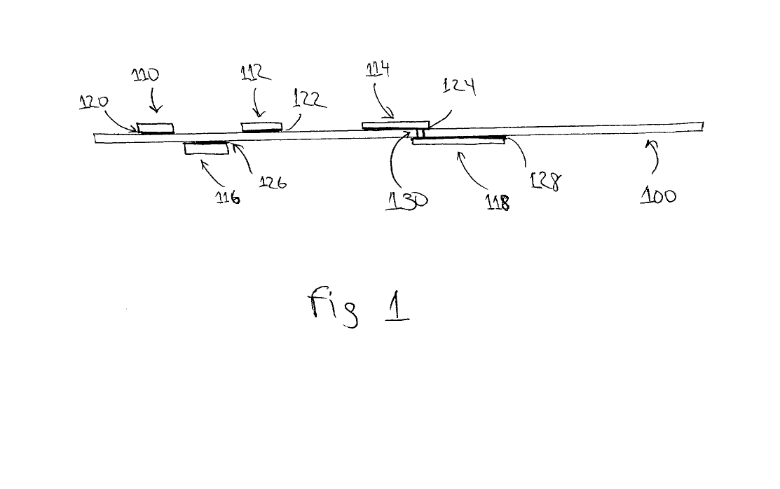

FIG. 1 shows a cross section of a printed circuit board known to the art. Substrate 100, which may be of fiberglass or other nonconductive materials, carries conductive traces 110, 112, 114, 116, and 118. These conductive traces are typically copper, and are secured to substrate 100 by adhesive 120, 122, 124, 126, 128. Thicknesses shown are exaggerated for clarity. In typical practice, substrate 100 ranges from 0.4 mm (0.015 in) to 3.0 mm (0.120 in) in thickness, and conductive traces 110-118 range from 0.017 mm (0.0007 in) to 0.076 mm (0.003 in) in thickness. Printed circuit boards are commonly produced through photolithographic processes known to the art.

FIG. 1 also shows via 130, connecting traces 114 and 118. Via 130 not only provides a conductive path between traces 114 and 118, it also provides a mechanical anchor, holding traces 114 and 118 to the substrate.

While a two-layer board is shown in FIG. 1, multi-layer boards are common, consisting of conductive layers sandwiched between layers of insulating substrate. In such multilayer boards, vias may extend through one or more substrate layers, providing connections between traces.

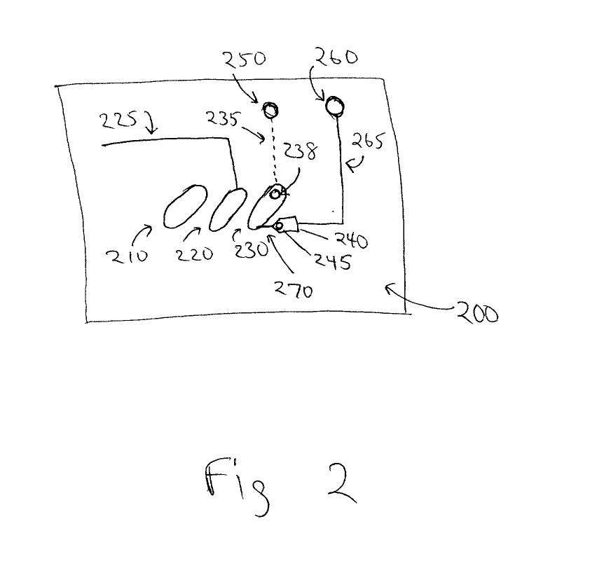

FIG. 2 shows a top view of a printed circuit board. Substrate 200 has conductive pads 210, 220, 230, and 240. Trace 225 connects pad 220 to other circuitry not shown. Buried trace 235 connects pad 230 to test point 250. A buried trace is a trace contained in an intermediate layer of a multilayer board. Buried trace 235 is connected electrically to pad 230 by via 238, and to test pad 250 by the via forming the test pad. Trace 265 connects pad 240 to test point 260.

Pad 240 has via 245 located close to trace 270. Trace 270 is a sacrificial trace, in accordance with the present invention. Sacrificial trace 270 is deliberately made fragile. It is made as narrow as possible given the fabrication process, and via 245 is located close to the margin of pad 240 to provide an anchor. In this application, via 245 is used as a mechanical anchor, providing additional anchoring to pad 240. In the preferred embodiment, sacrificial trace 270 is 0.102 mm (0.004 in) wide and 0.229 mm (0.009 in) long. Pad 240 could also be the top surface of a via, providing an anchor to one end of sacrificial trace 270.

An alternative sacrificial trace may be formed by introducing one or more stress concentration points into a trace. These stress concentration points provide locations where the trace is more likely to fail under mechanical stress. Suitable stress concentration points include nicks in the trace, notches, or abrupt narrowing of the trace. While such stress concentration points may be located anywhere along the sacrificial trace they are preferred near the anchor point.

Assume pads 210, 220, and 230 are pads for a large surface-mount device such as a BGA integrated circuit package, a multi-chip module, filter, or the like. Stresses causing relative mechanical displacement, such as thermal expansion and contraction cycles, rapid acceleration or deceleration during shipping or drop tests, or through board handling, can flex substrate 200. If the substrate flexes, and the device connected to pads 210, 220, and 230 does not flex equally, stress is applied to the pads. The stress may be sufficient to cause the adhesive holding a pad to the surface to fail, resulting in delamination of the pad.

If pad 220 were to delaminate, it is likely that a portion of trace 225 would be pulled up with pad 220. This produces a latent failure, either through providing intermittent contact, or an eventual complete failure.

The present invention detects delamination by introducing a sacrificial trace that is designed to fail if the pad to which it is attached delaminates. Sacrificial trace 270 connects pad 240 and pad 230. Pad 240 has via 245 close to the end of sacrificial trace 270, providing a mechanical anchor far stronger than the adhesive holding pads and traces to substrate 200. If pad 230 delaminates and lifts off the board, sacrificial trace 270 will be severed, as via 245 on pad 240 secures pad 240 to substrate 200.

The embodiment shown detects the failure of sacrificial trace 270 by opening the electrical circuit between test points 250 and 260. These test points would be used during production and test of the populated printed circuit board. While two separate test points are shown in the figure, alternate embodiments are also possible. For example, if pad 240 were tied to a common ground, any similarly grounded point on the circuit board could be used for test point 260. Alternative detection methods include using device logic to sense failure of sacrificial trace 270. For example using a digital integrated circuit, the integrated circuit node connected to pad 230 could be internally pulled up to a logical high, and pulled to a logical low by pad 240 through sacrificial trace 270. As long as sacrificial trace 270 is intact, the node connected to pad 230 will be low. A high level on the node connected to pad 230 indicates a failure of sacrificial trace 270, which can be further signaled through the device. Sacrificial trace 270 could also be used to carry important device signals, such that its failure renders the overall device inoperable.

In the case of devices such as BGA integrated circuit packages, MCM packages, and the like, it has been found that the maximum stress occurs at the corners of the package. For this reason it is advantageous to place sacrificial trace 270 on corner pads of such a device.

The foregoing detailed description of the present invention is provided for the purpose of illustration and is not intended to be exhaustive or to limit the invention to the precise embodiments disclosed. Accordingly the scope of the present invention is defined by the appended claims.

What is claimed is:

1. A printed circuit board comprising:
a substrate,
a target pad on the surface of the substrate,
an anchor pad adjacent to the target pad, and
a sacrificial trace connecting the target pad and the anchor pad.

2. The printed circuit board of claim 1, further comprising:
a first test pad on the surface of the substrate, the first test pad electrically connected to the target pad, and
a second test pad on the surface of the substrate, electrically connected to the anchor pad.

3. The printed circuit board of claim 1, further comprising:
means for testing electrical continuity between the target pad and the anchor pad.

4. The method of detecting a delaminated pad on a printed circuit board comprising:
placing a target pad on the surface of the printed circuit board,
placing an anchor pad adjacent to the target pad on the surface of the printed circuit board,
connecting the target pad to the anchor pad by a sacrificial trace,
anchoring the anchor pad to the substrate with a via near the sacrificial trace, and
testing for electrical continuity between the target pad and the anchor pad.

5. The method of claim 4 where the testing for electrical continuity between the target pad and the anchor pad is performed by testing means located on the printed circuit board.

6. The method of claim 4 where the testing for electrical continuity between the target pad and the anchor pad is performed by testing means located off the printed circuit board.
